(19) United States
(12) Patent Application Publication
(10) Pub. No.: US 2022/0315336 A1
(43) Pub. Date: Oct. 6, 2022

(54) LOADER TOOL

(71) Applicant: Microsoft Technology Licensing, LLC, Redmond, WA (US)

(72) Inventors: Benjamin Chaoning LIU, Silver Spring, MD (US); Miriam Esther MARIZAN, Baltimore, MD (US)

(73) Assignee: Microsoft Technology Licensing, LLC, Redmond, WA (US)

(21) Appl. No.: 17/222,507

(22) Filed: Apr. 5, 2021

(51) Int. Cl. B65G 1/10; B65G 69/24

(52) U.S. Cl. CPC B65G 1/10; B65G 69/24

(57) ABSTRACT

The discussion relates to loading electronic assemblies on multi-shelf chasses. One example can include a vertical positioning mechanism configured to be secured to a multi-shelf chassis and to align a carrier supporting an electronic assembly with an individual shelf of the multi-shelf chassis. The example can also include a horizontal positioning mechanism configured to extend the carrier along the individual shelf and an anti-deflection mechanism configured to reduce downward deflection of the carrier when the carrier is extended into the electronic assembly loader tool along the individual shelf.

### BACKGROUND

Electronics, such as processors, memory, etc. continue to get physically smaller while offering enhanced performance. Often these electronics are employed in space-constrained operating environments where high electronic density is desired. In some cases, high density can be achieved with a chassis that includes multiple shelves. Sets of electronics can be positioned on the shelves to achieve high electronic density. However, as mentioned above, the diminutive size and/or delicate nature of the electronic components and/or the chassis can make it difficult for a human to insert and/or withdraw sets of electronics from the shelves using their hands. The present concepts can address these and/or other issues.

### BRIEF DESCRIPTION OF THE DRAWINGS

The accompanying drawings illustrate implementations of the concepts conveyed in the present document. Features of the illustrated implementations can be more readily understood by reference to the following description taken in conjunction with the accompanying drawings. Like reference numbers in the various drawings are used wherever feasible to indicate like elements. In some cases, parentheticals are utilized after a reference number to distinguish like elements. Use of the reference number without the associated parenthetical is generic to the element. Further, the left-most numeral of each reference number conveys the figure and associated discussion where the reference number is first introduced.

FIGS. 1A, 1B, 2A-2H, 3A-3C, 4A, 4B, 5A, 5F, and 6A-6D show perspective views of example loader tool systems in accordance with some implementations of the present concepts.

FIGS. 3D-3F, 4C, and 5B-5E show elevational views of example loader tool systems in accordance with some implementations of the present concepts.

FIG. 7 shows a flowchart of a loader tool method that can implement some of the present concepts in accordance with some implementations.

### DETAILED DESCRIPTION

The present concepts relate to solutions for loading and unloading electronic assemblies from a multi-shelf chassis. The diminutive sizes involved and/or the delicate nature of the electronic assembles tends to preclude a user from accomplishing these processes by hand. The present concepts can relate to loader tools that can perform these and/or other processes.

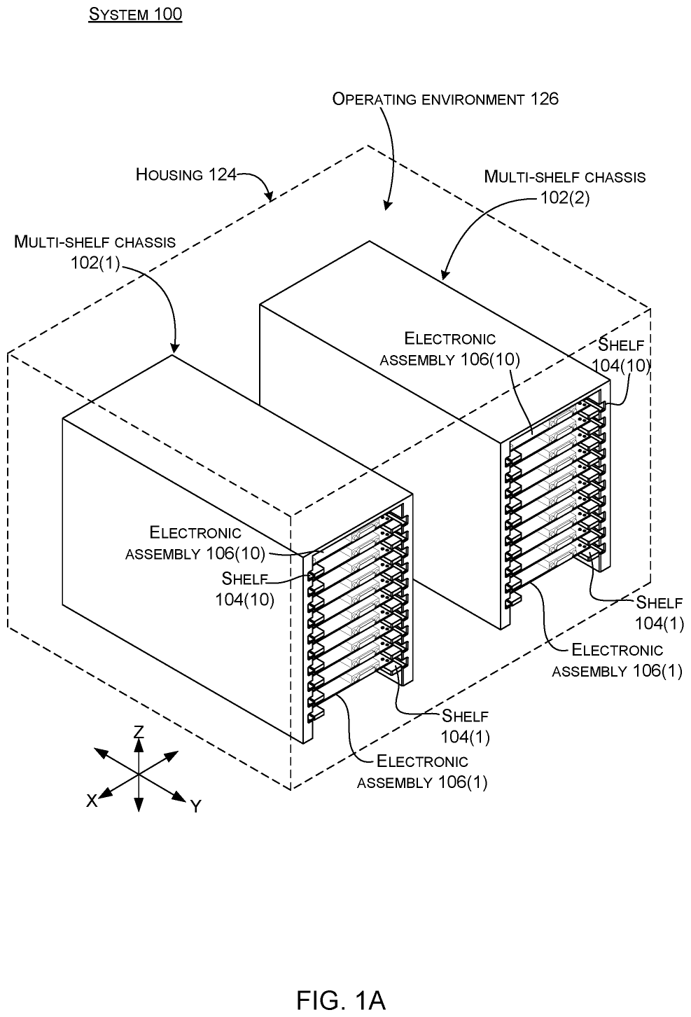

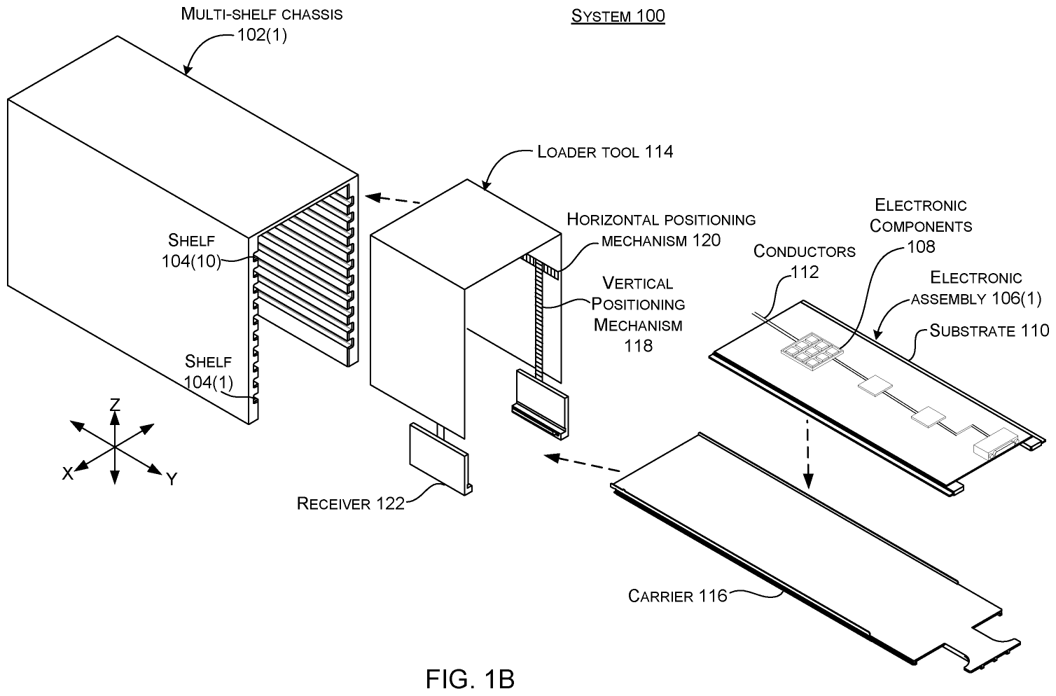

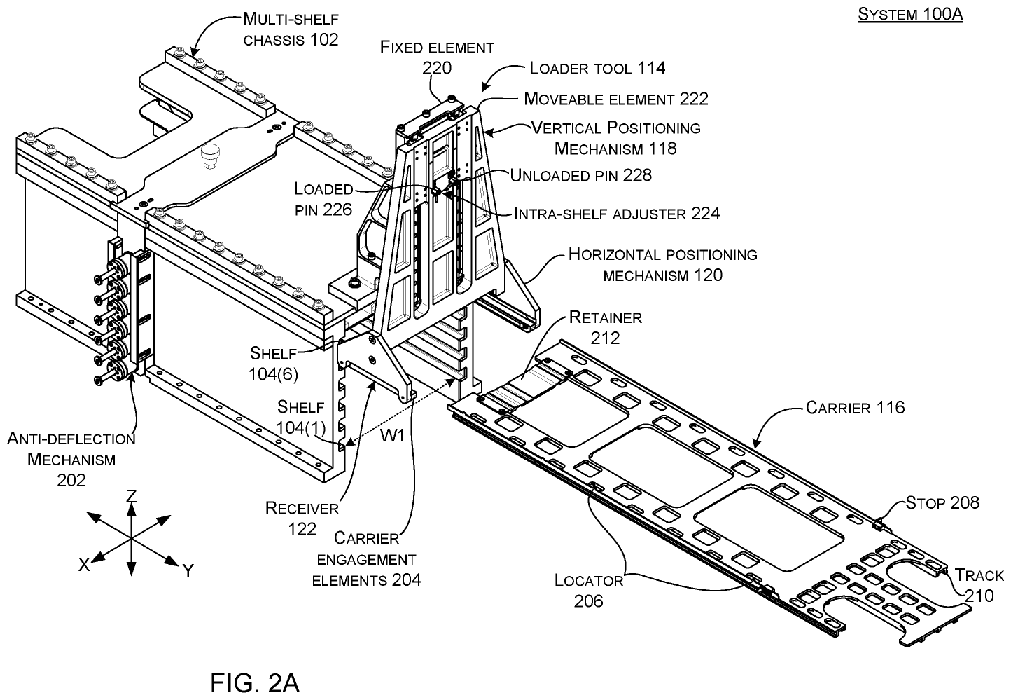

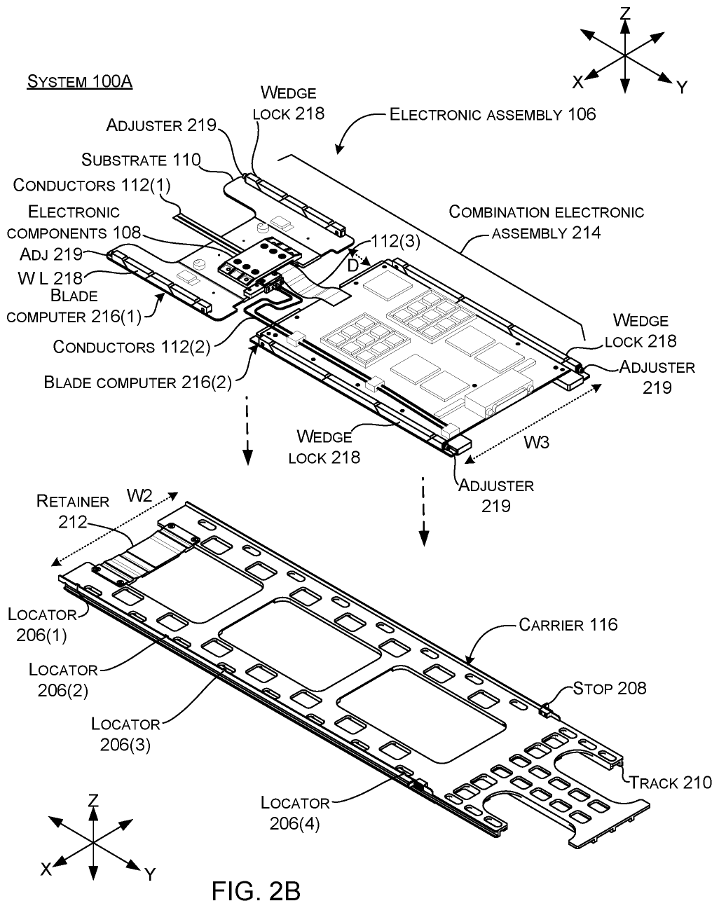

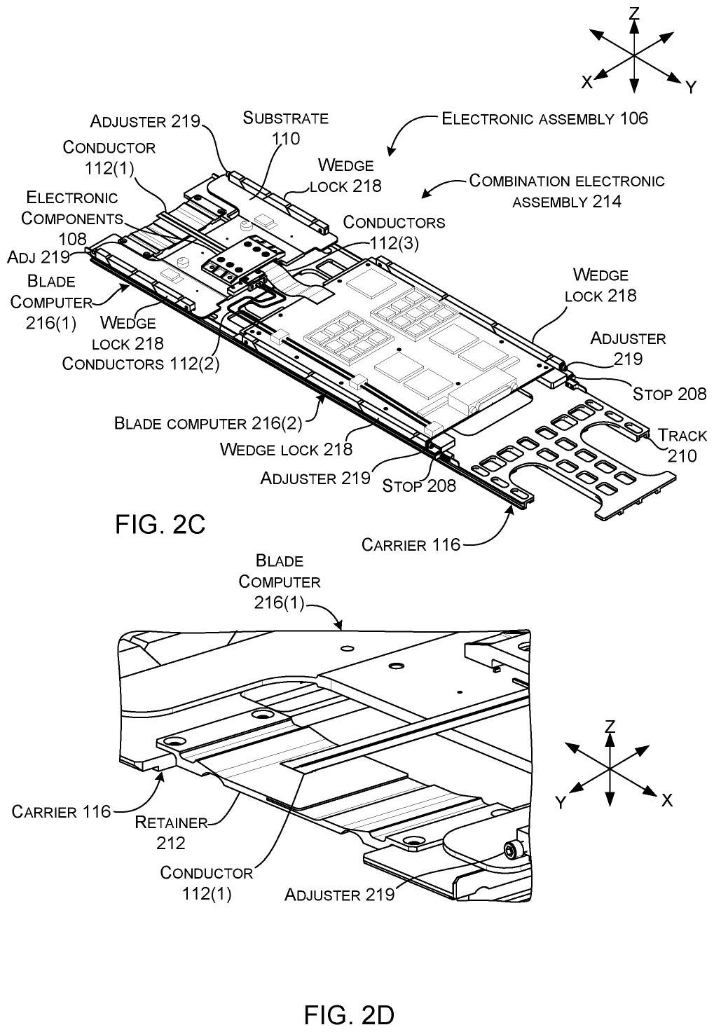

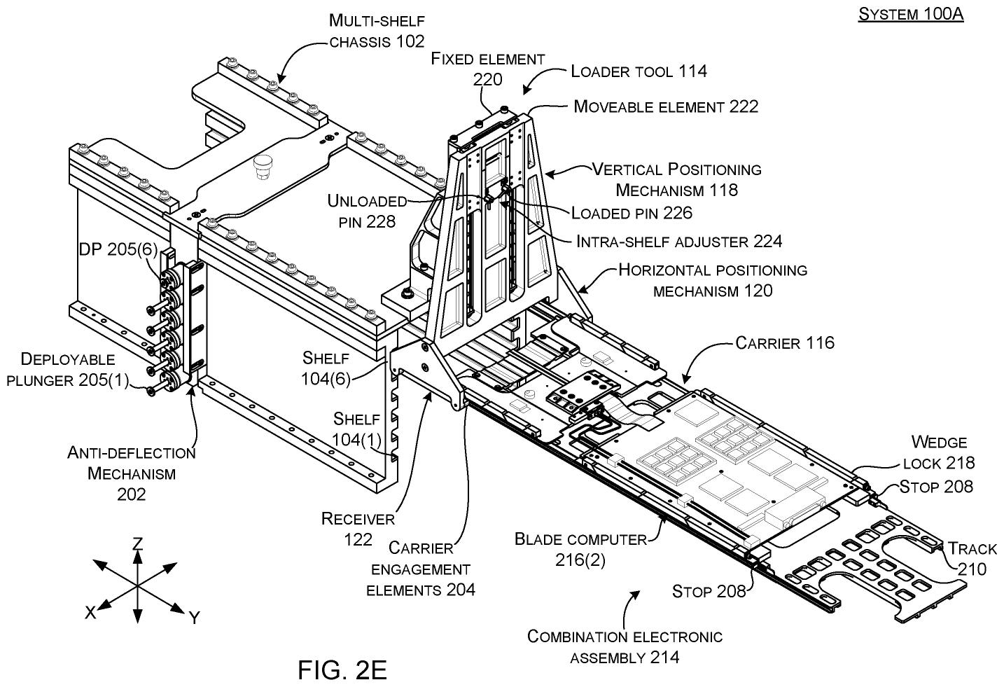

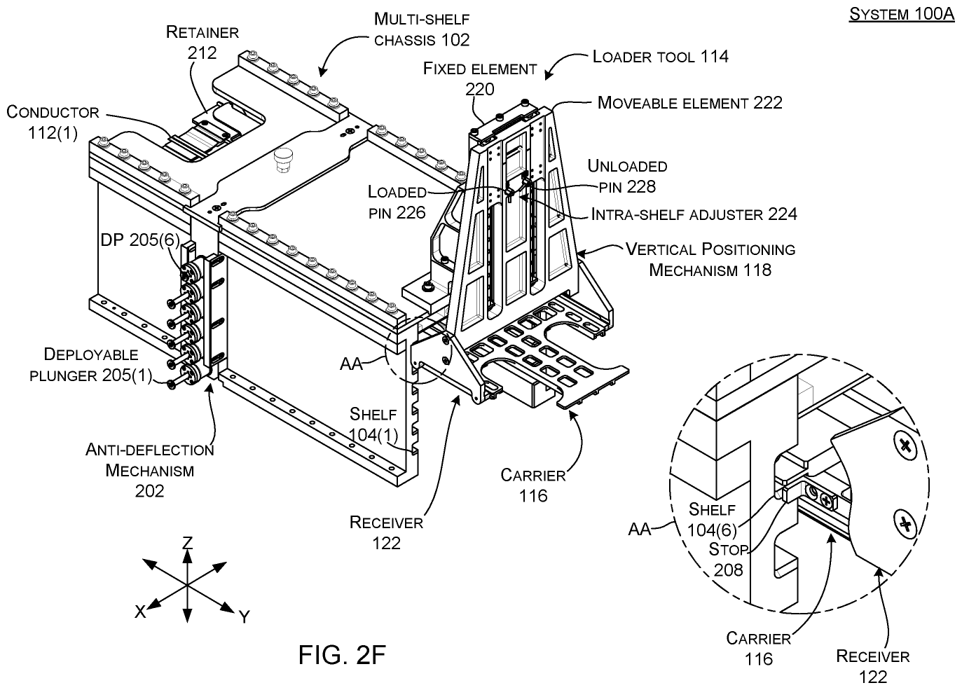

Introductory FIGS. 1A and 1B collectively show a system 100 that can include a multi-shelf chassis 102 that defines multiple shelves 104. In this example, the multi-shelf chassis 102 defines ten shelves 104, though other numbers of shelves are contemplated. For instance, FIGS. 2A-2H show an example multi-shelf chassis 102 with six shelves. Other implementations may include more shelves, such as tens or hundreds of shelves.

The shelves 104 can support electronic assemblies 106. In some configurations, the electronic assemblies 106 can include various electronic components 108 positioned on a substrate 110 or multiple substrates. Example electronic components 108 can include various processors, such as central processing units (CPUs), graphical processing units (GPUs), field programmable gate arrays (FPGAs), etc., memory, storage, etc. Example substrates 110 can include circuit boards, flexible printed circuit boards, and/or metal substrates, among others. The substrates 110 can physically support the electronic components 108, electrically insulate the electronic components, and/or function as heat sinks for the electronic components, among other functions. In some cases, the electronic components 108 can be cooled by cooling the substrates 110, or a metal plate that is positioned relative to the substrate, such as between the substrate and the electronic components or on an underside of the substrate.

Conductors 112, such as flexible conductive tapes can be employed to interconnect individual electronic components within an electronic assembly and/or to connect the electronic assembly to other electronic assemblies, and/or to other elements, such as buses, routers, etc.

The multi-shelf chassis 102 can provide and/or allow various connections to the electronic assemblies 106 positioned on the shelves 104, such as via conductors 112. For instance, the multi-shelf chassis 102 may supply one or more network connections and/or power supply connections, among others, to the electronic assemblies 106.

A loader tool 114 can be employed for loading and/or unloading electronic assemblies 106 into and/or out of the multi-shelf chassis 102. In some implementations, the loader tool 114 can include a carrier 116, a vertical positioning mechanism 118, and/or a horizontal positioning mechanism 120. The horizontal positioning mechanism 120 can include a receiver 122. An individual electronic assembly 106 can be positioned on (e.g., loaded on) carrier 116. The loaded carrier 116 can be positioned on the receiver 122 of the loading tool 114. The vertical positioning mechanism 118 can position the carrier 116 relative to an individual shelf 104, such as an empty shelf. The horizontal positioning mechanism 120 can extend the carrier 116 into the multi-shelf chassis 102 so that the electronic assembly 106 can be positioned on the empty shelf. The horizontal positioning mechanism 120 can then withdraw the carrier 116.

The loader tool 114 can allow electronic assemblies 106 to be positioned on the stacked shelves 104 of the multi-shelf chassis 102. This can provide a very high density of electronic assemblies 106 in a volume occupied by the multi-shelf chassis 102. This high density can provide various advantages. For instance, the high density can decrease the length of conductors that communicatively couple electronic assemblies 106 on different shelves 104. Shortening the conductor length may decrease latency and provide higher performance for the electronic components of the multi-shelf chassis.

In some implementations, one or more multi-shelf chasses 102 may be positioned in a housing 124. The housing may control the operating environment 126 for the electronic components of the multi-shelf chassis 102. The operating environment may include various operating conditions, such as temperature (e.g., temperature regulation or cooling), compute load (e.g., processing load), etc. Controlling the operating conditions can be very resource intensive. The high density of electronic assemblies 106 provided by the multi-shelf chassis 102 can allow the housing 124 to be smaller and thus reduce the volume that has to be controlled. Viewed another way, the use of the loader tool 114 can allow the dimensions of the multi-shelf chassis 102 to be reduced to satisfy dimensional constraints imposed on and/or by the housing 124 while simultaneously satisfying performance parameters expected of the electronic assemblies. Alternatively or additionally, as mentioned above, the compact stacked nature can increase compute density and decrease conductor length and hence latency for a given amount of compute resources contained in an individual multi-shelf chassis 102 and/or a set of co-located multi-shelf chasses (e.g., multi-shelf chasses 102(1) and 102(2) of FIG. 1A). The loader tool 114 provides a technical solution that allows the compact multi-shelved chasses to be loaded and unloaded with the electronic assemblies.

FIGS. 2A-2H collectively show another system 100A. The use of the suffix “A” is intended to convey that various components of system 100A may be different from those of system 100 described above (and/or other implementations) and/or system 100A may include different components than system 100 (and/or other implementations).

In this case, as shown in FIG. 2A, loader tool 114 can include an anti-deflection mechanism 202 and carrier engagement elements 204 on the receiver 122. The carrier engagement elements 204 can receive the carrier 116 on the loader tool 114 and allow horizontal extension of the carrier into the multi-shelf chassis 102. The anti-deflection mechanism 202 can function to help maintain an intended shape, orientation, and/or position of the carrier 116 when the carrier is extended into the multi-shelf chassis. In this case, the anti-deflection mechanism 202 is manifest as pairs of opposing deployable plungers 205 (e.g., one pair of deployable plungers per shelf 104). This aspect will be described in more detail below.

In this implementation, as shown in FIGS. 2B and 2C, the carrier 116 can include locators 206, stops 208, tracks 210, and/or retainers 212. In this case, the carrier 116 can accommodate a combination electronic assembly 214 that includes at least two electronic assemblies 106 that can be interconnected by conductors 112. In this example, the two electronic assemblies 106 are manifest as blade computers 216. One or both of the electronic assemblies 106 can include wedge locks 218. The wedge locks 218 can work cooperatively with wedge lock adjusters 219.

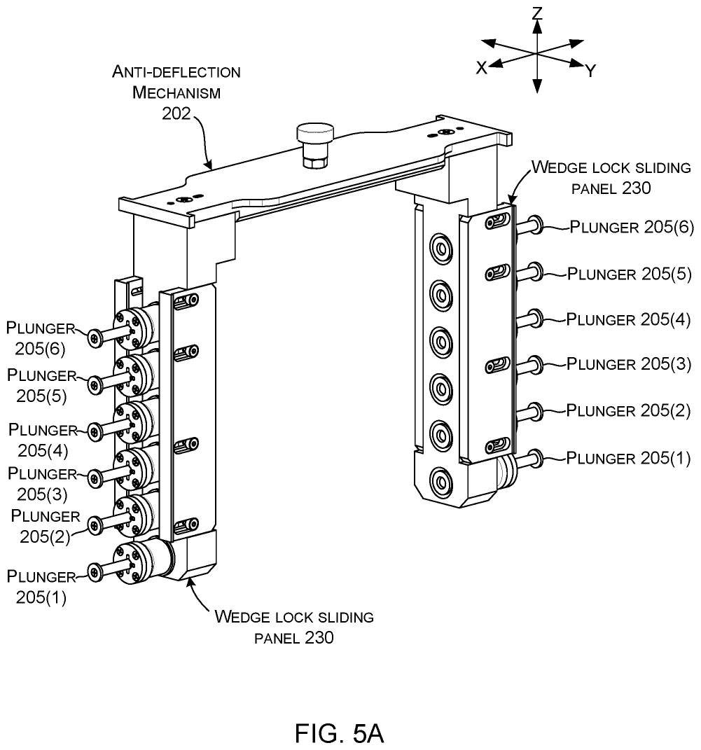

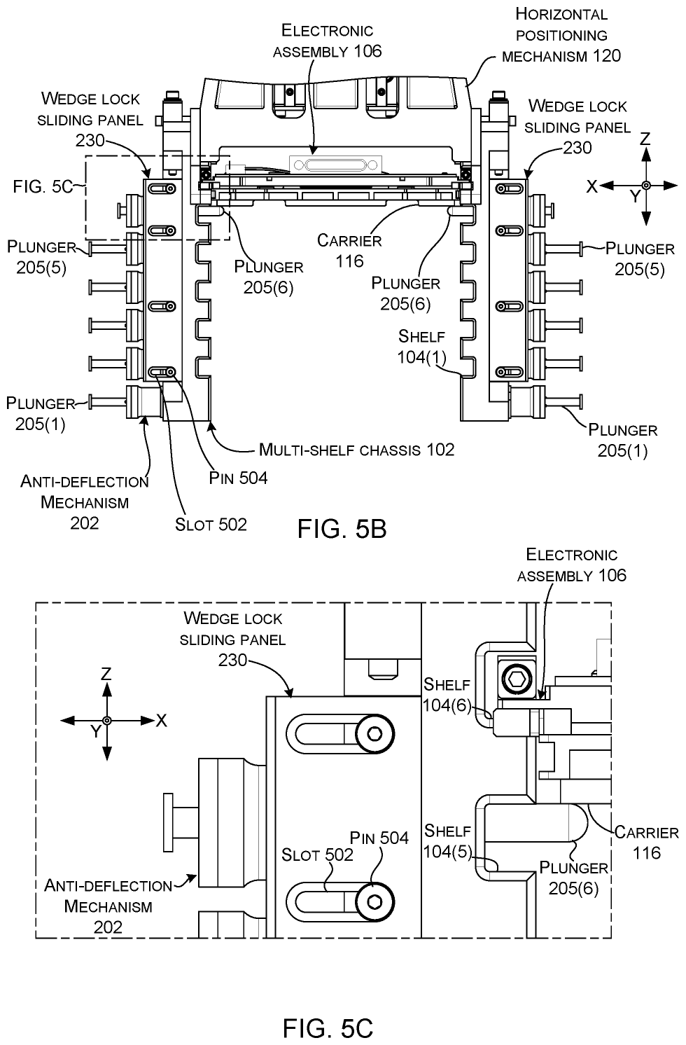

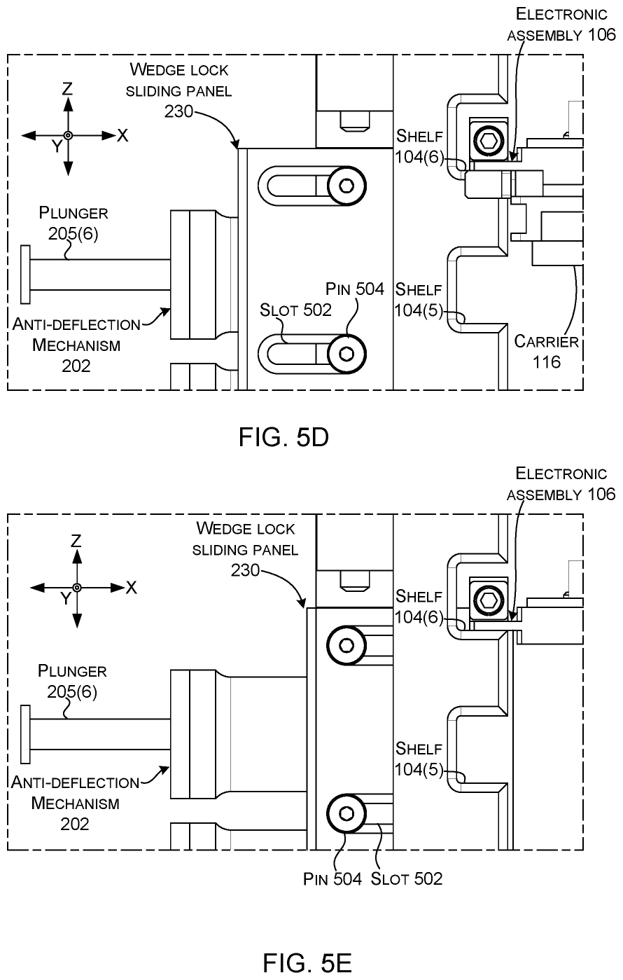

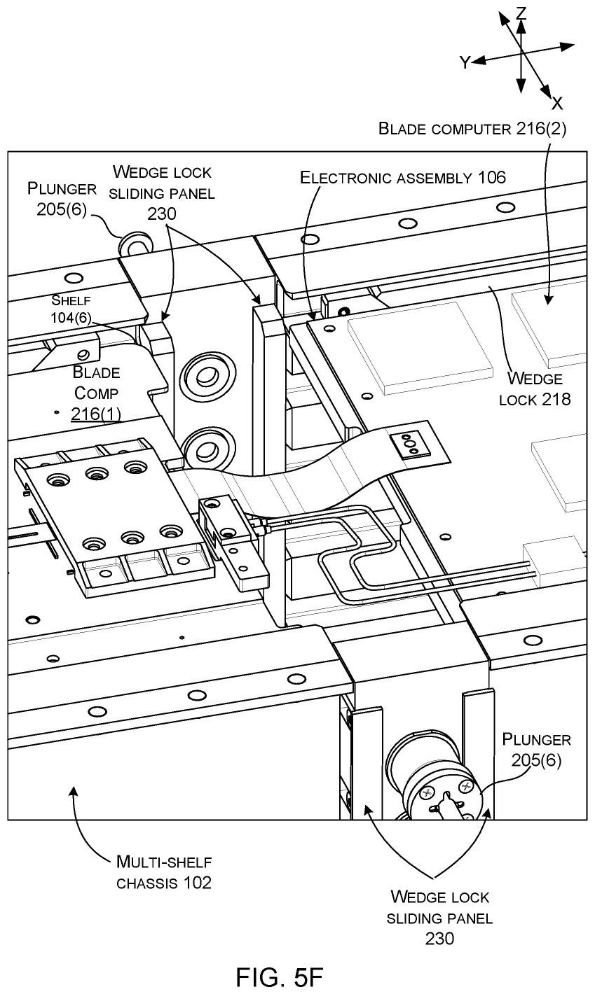

The wedge lock adjusters 219 can be accessed from outside the multi-shelf chassis 102. In this case, the wedge lock adjusters 219 for blade computer 216(2) can be accessed from the front (e.g., loading end) of the multi-shelf chassis 102 and the wedge lock adjusters (e.g., ‘adjusters’) 219 for blade computer 216(1) can be accessed from the back of the multi-shelf chassis 102. Adjusting the adjusters 219 can change dimensions of the wedge locks 218 and cause the wedge locks to be forced against opposing surfaces of the multi-shelf chassis 102 to lock the blade computers in place. The wedge locks are described in more detail below relative to FIG. 5F.

In this example, the electronic assemblies 106(1) and 106(2) are physically distinct and separate from one another and are electrically coupled by conductors 112(2) and 112(3). These conductors 112(2) and 112(3) are flexible and as such do not add any/significant structural integrity between the electronic assemblies 106(1) and 106(2). Thus, the angle and/or distance between the electronic assemblies 106(1) and 106(2) will readily change unless external structural integrity is provided. Further, any structural forces imparted on the conductors 112(2) and/or 112(3) and/or bending on the conductors could damage the conductors and/or their connections to the electronic components 108. The two separate electronic assemblies 106(1) and 106(2) would be essentially impossible for a user to install manually in multi-shelf chassis 102.

Carrier 116 can provide external structural integrity to the two separate electronic assemblies 106(1) and 106(2). In this case, carrier 116 is configured to support the electronic assemblies 106(1) and 106(2) in the illustrated co-planar orientation. The carrier 116 is further configured to maintain a defined distance ‘D’ between the two electronic assemblies 106. This can be achieved at least in part by the locators 206. In this case, the locators 206 can be protuberances that fit into corresponding recesses (not visible) in the electronic assemblies 106. The carrier 116 can be further configured to support conductors 112, such as conductor 112(1) so that the conductors do not experience deflection forces that could damage the conductor and/or its connection to electronic components of the electronic assemblies during installation into the multi-shelf chassis 102. For instance, as shown in FIGS. 2C and 2D, retainer 212 can support conductor 112(1) to avoid deflection and/or damage.

As mentioned above in this example, electronic assemblies 106(1) and 106(2) are manifest as first and second blade computers 216(1) and 216(2) that can operate cooperatively (e.g., each of the blade computers may be configured to achieve a portion of a functionality). The first blade computer 216(1) and the second blade computer 216(2) may function in similar operating environments. For instance, both blade computers may operate at the same operating temperature. In other cases, the blade computers may operate at different operating temperatures. For example, the first blade computer 216(1) may operate at a first temperature, while second blade computer 216(2) may operate at a second different temperature. The different operating temperatures may preclude the blade computers from being integrated onto a single substrate. However, when positioned on separate substrates that are coupled by conductors 112, a separate operating environment can be provided for the blade computers, such as by housing 124 discussed relative to FIG. 1A, while minimizing/reducing conductor length connecting the electronic assemblies 106(1) and 106(2).

FIG. 2B shows the two blade computers 216(1) and 216(2) positioned above the carrier 116. FIG. 2C shows carrier 116 supporting the two separate blade computers 216(1) and 216(2) (e.g., loaded carrier). As mentioned, the carrier 116 can support one or more of the conductors 112 to prevent deflection and/or damage to the conductors. In this implementation, the carrier includes locators 206 for maintaining the blade computer 216(1) and 216(2) at the desired relative positions in the x and y reference directions. More specifically, locators 206(1) and 206(2) position blade computer 216(1) and locators 206(3) and 206(4) position blade computer 216(2) a defined distance from blade computer 216(1).

As shown in FIGS. 2A and 2B, the carrier 116 can include tracks 210 or other alignment elements to engage the loader tool's carrier engagement elements 204. The tracks 210 can move relative to the carrier engagement elements 204. Further, the carrier's stops 208 can define an extent of horizontal displacement of the carrier 116 into the multi-shelf chassis 102.

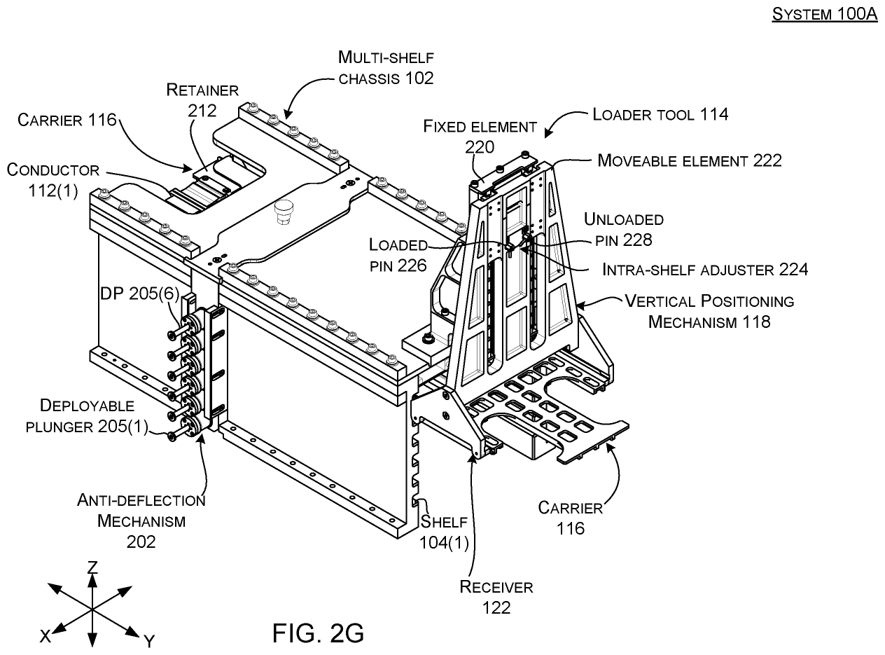

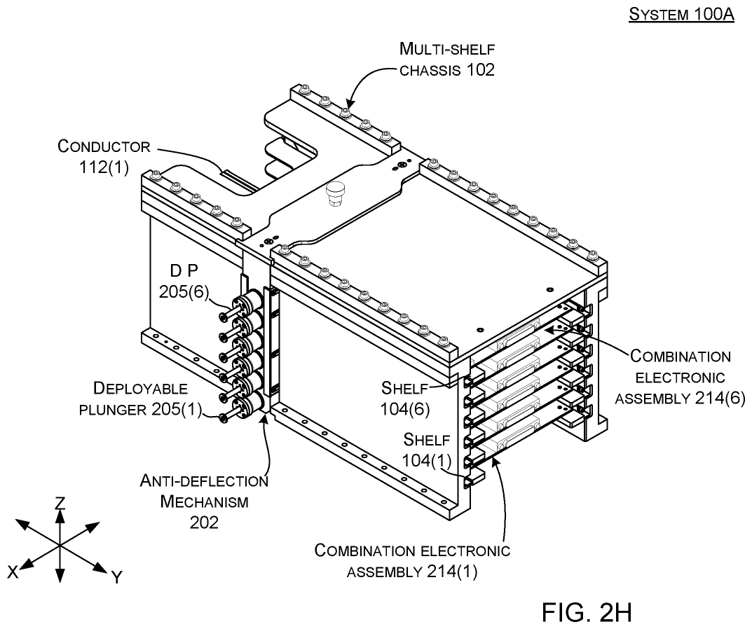

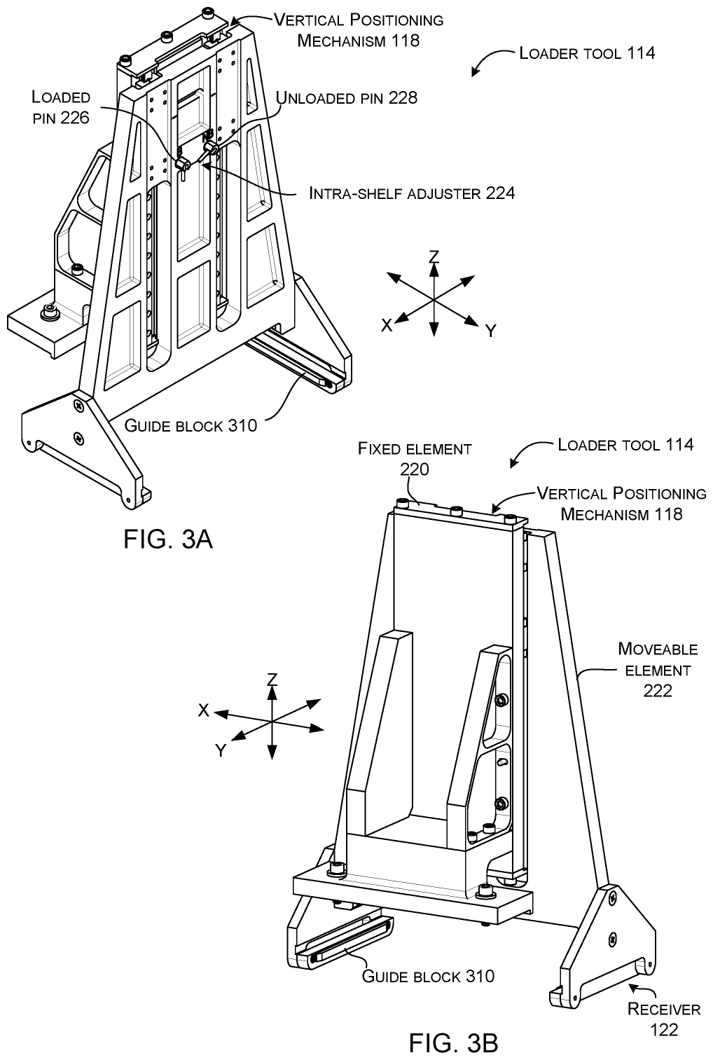

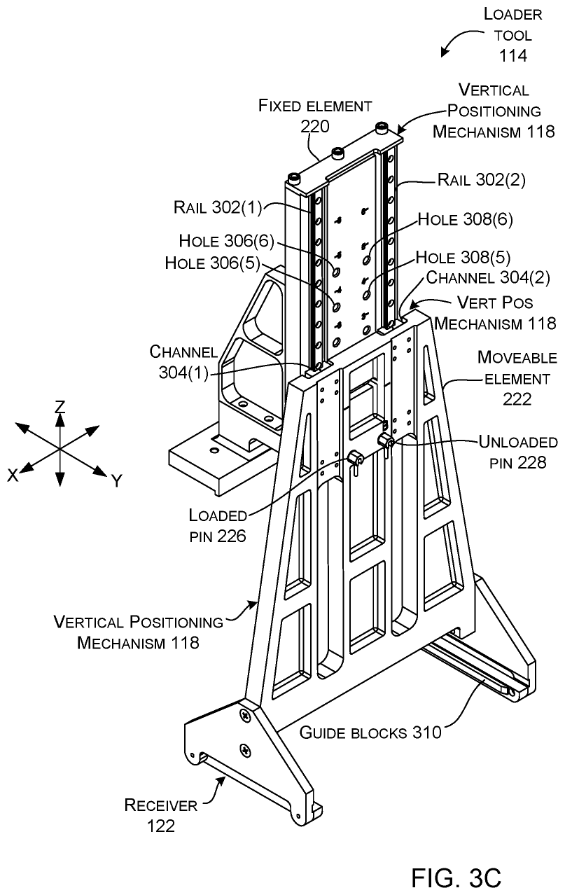

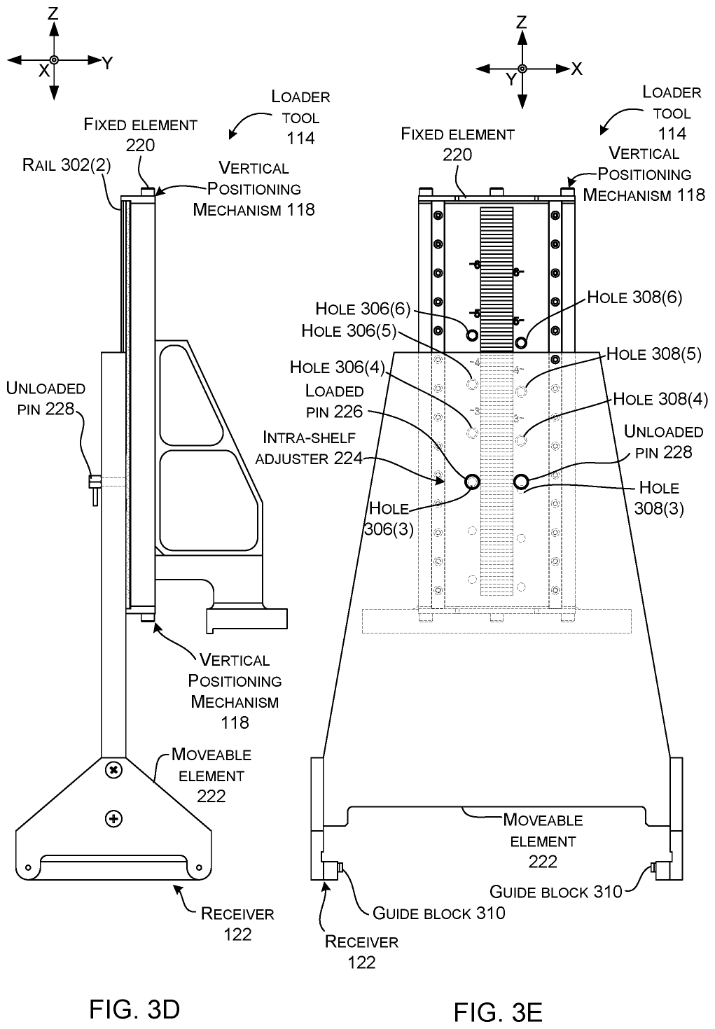

In this implementation, as shown in FIG. 2A, the loader tool's vertical positioning mechanism 118 can also include a fixed element 220 and a moveable element 222. The fixed element 220 can be secured to the multi-shelf chassis 102. The moveable element 222 can move vertically relative to the fixed element 220. The moveable element 222 can also include an intra-shelf adjuster 224. The intra-shelf adjuster 224 can provide fine granularity control of the carrier 116 relative to an individual shelf 104. In this case, the intra-shelf controller 224 can include a loaded pin 226 and an unloaded pin 228. This aspect will be described below relative to FIGS. 3A-3F.

FIG. 2E shows the loader tool 114 secured to the multi-shelf chassis 102 and the receiver 122 aligned with shelf 104(6). The carrier 116, loaded with the combination electronic assembly 214, is positioned in the loader tool 114 (e.g., the tracks 210 are positioned in the carrier engagement elements 204 of the receiver 122). FIG. 2F shows the carrier 116 horizontally displaced into multi-shelf chassis 102 to deliver the combination electronic assembly 214 to shelf 104(6). As shown by enlargement ‘AA,’ the carrier's stop 208 can physically engage the multi-shelf chassis 102 to define the extent of the horizontal displacement. At this point, the pair of opposing deployable plungers 205(6) are deployed to support the extended carrier 116.

FIG. 2G shows the deployable plungers 205(6) retracted. At this point, the combination electronic assembly 214 (occluded by the multi-shelf chassis 102) is positioned relative to shelf 104(6) and the carrier 116 can be withdrawn.

FIG. 2H shows the multi-shelf chassis 102 after the loading process has properly located a combination electronic assembly 214 on each shelf 104. At this point, the loader tool 114 had been removed from the multi-shelf chassis 102. In other implementations, the loader tool may be permanently attached to the multi-shelf chassis 102 and/or be an integral part of the multi-shelf chassis 102.

From one perspective, system 100A can provide a technical solution that can allow a user to smoothly insert and remove each combination electronic assembly 214 from the multi-shelf chassis 102 without damaging them. Due to the delicate nature of the conductors 112 (e.g., flexible cables) connecting the two blade computers 216 and short chassis pitch between each slot, it would be impossible for a technician to install the combination electronic assembly 214 by moving it through the length of the multi-shelf chassis to its designated location without damaging the components on the combination electronic assembly 214 above and below the shelf in the multi-shelf chassis 102 where the installation is occurring. The loader tool 114 can allow a technician to precisely insert or remove any electronic assembly 106 in the multi-shelf chassis 102 (for maintenance purposes, for example) without disturbing the other electronic assembly 106 on other shelves 104. Further, the loader tool's carrier 116 can provide a technical solution that maintains the blade computers in a planar orientation, at a fixed distance apart, and supports the conductors during the entire installation (and removal) process onto an individual shelf of the multi-shelf chassis.

To review some of the aspects described above, in this implementation, the vertical positioning mechanism 118 includes fixed element 220 and moveable element 222. The fixed element 220 can be secured (in this case removably secured) to the multi-shelf chassis 102. The moveable element 222 can move vertically relative to the fixed element 220 to align the carrier 116 with an individual shelf 104. The moveable element 222 can also include intra-shelf adjuster 224 for adjusting the vertical height of the carrier 116 relative to the individual shelf 104 depending on whether or not the carrier 116 is loaded with an electronic assembly 106 (FIG. 2B). The intra-shelf adjuster 224 can have an upper loaded position (e.g., loaded height) and a lower unloaded position (e.g., unloaded height). The upper loaded position can raise the loaded carrier slightly so the electronic assembly 106 is carried by the carrier 116 slightly above the individual shelf. The lower unloaded carrier position can allow the carrier 116 to travel under the individual shelf 104. In this case, the intra-shelf adjuster 224 is manifest as loaded pin 226 and unloaded pin 228, though other configurations are contemplated. These facets are described in more detail below relative to FIGS. 3A-3F.

Some of the inventive concepts relate to a technical solution provided by a mechanical assist device (e.g., the loader tool 114) to handle delicate components instead of using bare human hands. The loader tool 114 can provide a consistent and precise position in front of the multi-shelf chassis 102 for the electronic assembly 106 to be inserted or removed from an individual shelf 104 of the multi-shelf chassis 102. Further, the loader tool 114 can allow any shelf 104 to be loaded or unloaded without regard to other shelves (e.g., there is no required order).

The carrier 116 can be utilized to carry and insert electronic assemblies 106, such as a combination electronic assembly 214 that includes two or more blade computers 216, for example, onto an individual shelf 104. The carrier 116 can allow all electronics, such as combination electronic assembly 214, to be positioned on an individual shelf 104 simultaneously, rather than sequentially loading, for example, one blade computer 216(1) onto the shelf and then another blade computer 216(2) onto the shelf 104. The carrier 116 can be made out of light weight and stiff material such as a ferrous or non-ferrous metal, polymer, or composite. In one example, the carrier can entail an Aluminum Alloy, such as 6061, for instance. The carrier 116 can be designed in such a way that a technician can insert or remove a full blade assembly (e.g., an entirety of the electronic assembly) on an individual shelf with little effort and without special manual dexterity.

The combination of the vertical positioning mechanism 118, the horizontal positioning mechanism 120, and/or the anti-deflection mechanism 202, can allow electronic assembly 106 to be smoothly inserted or removed without damaging other electronic assemblies 106 on other shelves and without regard to whether the other shelves are loaded or unloaded.

FIGS. 3A-3F collectively show loader tool 114. In this case, the vertical positioning mechanism 118 includes rails 302 and channels 304, though other configurations are contemplated. In this example, the rails 302 are positioned on the fixed element 220 and the channels 304 are positioned on the moveable element 222. In other configurations, the rails 302 could be positioned on the moveable element 222 and the channels 304 could be positioned on the fixed element 220.

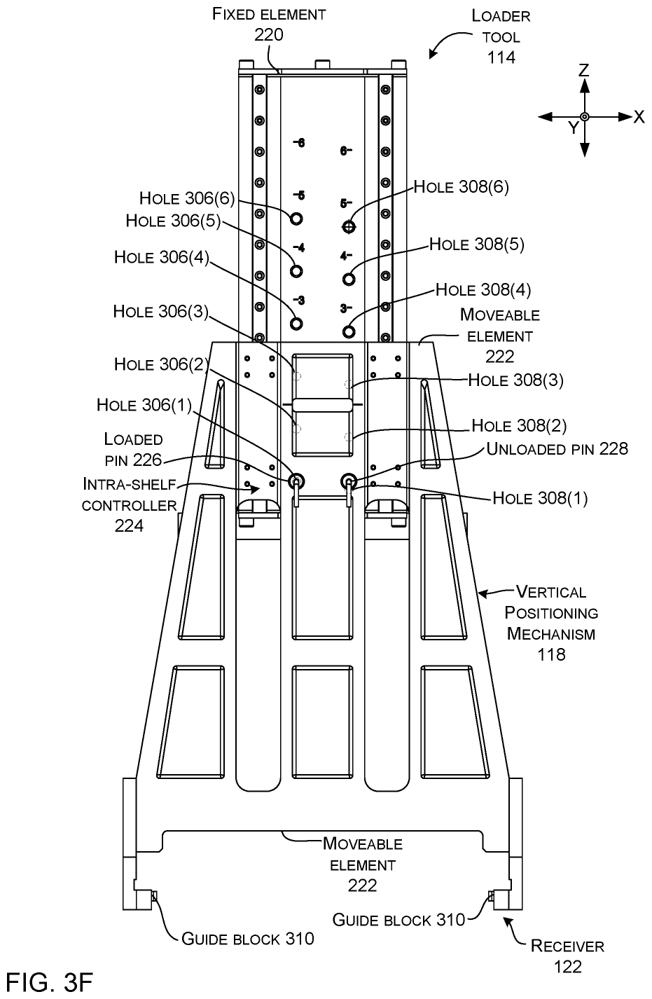

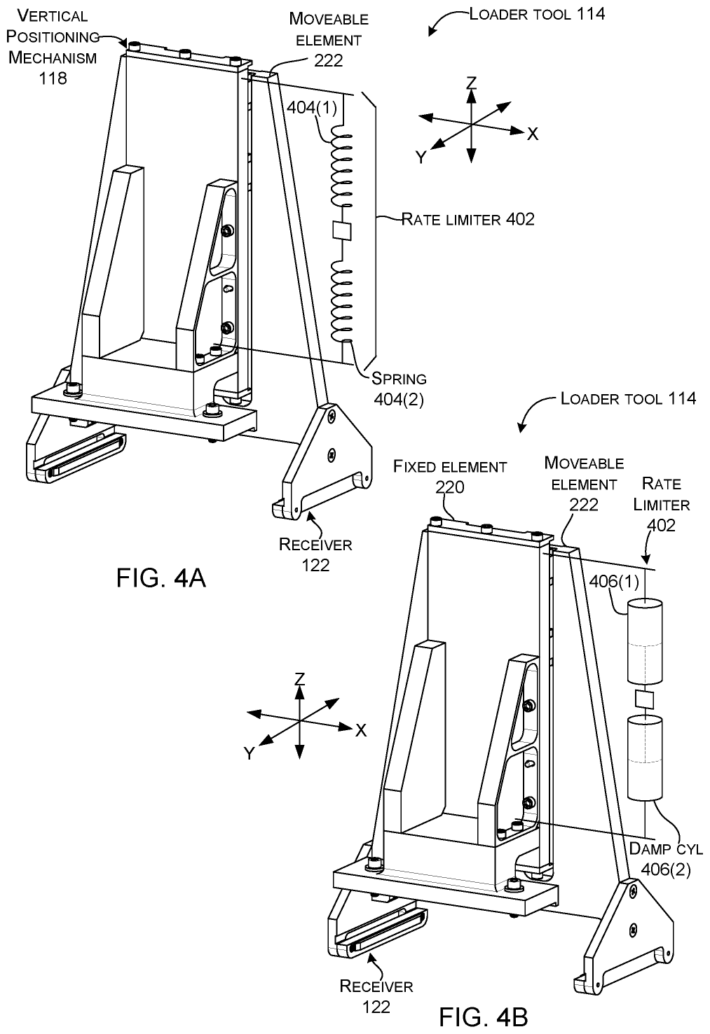

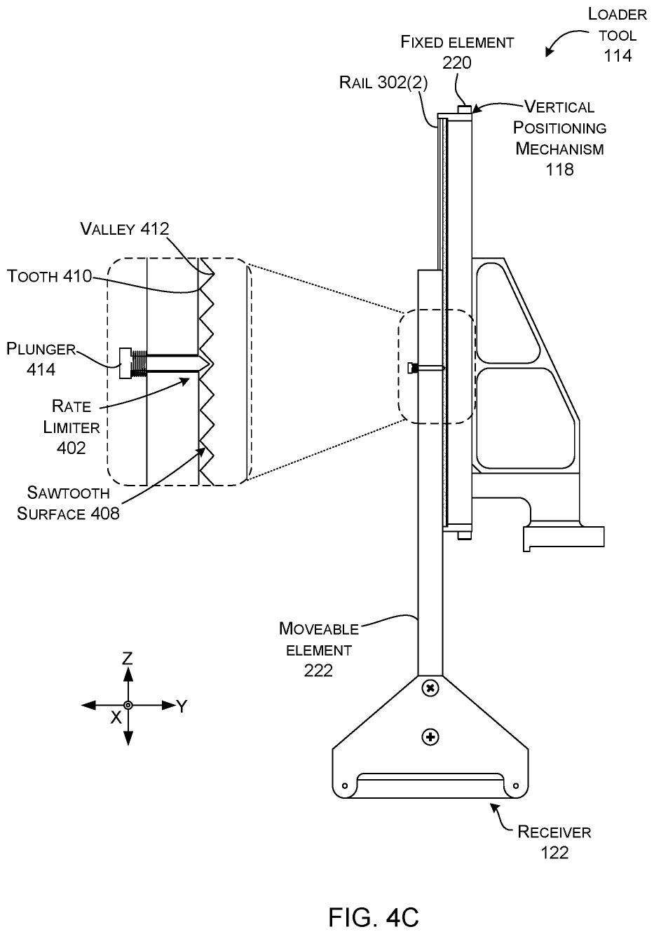

The combination of the rails 302 and the channels 304 allows the moveable element 222 to be precisely moved vertically with low friction to position the receiver 122 in front of an individual shelf 104 (FIG. 2E). Some implementations can employ rate limiters to control the rate at which the moveable element is moved. This aspect is described relative to FIGS. 4A-4C.

Once the receiver 122 and hence the carrier 116 is positioned relative to an individual shelf, the intra-shelf adjuster 224 can be employed. Specifically, slightly vertically offset holes 306 and 308 can be formed in the fixed element 220 relative to each shelf. As shown in FIG. 3E, the loaded pin 226 and the unloaded pin 228 are at the same height. However, relative to an individual shelf, the holes 306 and 308 are vertically offset (e.g., hole 306 is above hole 308). As such, either loaded pin 226 can be inserted into hole 306 (e.g., the loaded hole) or unloaded pin 228 can be inserted into hole 308 (e.g., the unloaded hole), but not both simultaneously. During the loading process, the loaded carrier 116 can be positioned in front of a target shelf and then the loaded pin 226 can be inserted into the respective hole 306 to precisely align the loaded carrier relative to the shelf. FIG. 3F shows the loaded position for the first shelf 104(1). For purposes of explanation, assume that the target shelf is shelf 104(3) as shown in FIG. 3E.

In the illustrated condition shown in FIG. 3E, the loaded pin 226 is aligned with and inserted into hole 306(3), while unloaded pin 228 is above hole 308(3). This allows the carrier 116 (FIG. 2E) to be horizontally displaced/deployed with combination electronic assembly 214 slightly above the shelf 104(3). In this case, the term ‘slightly’ means that the carrier 116 does not contact the shelf 104(3) during horizontal deployment and the combination electronic assembly 214(3) supported by the carrier does not contact the shelf 104(3), the overlying shelf 104(4), or another combination electronic assembly 214(4) positioned on the overlying shelf 104(4) during horizontal deployment.

This process can be reversed to unload combination electronic assemblies 214 from individual shelves 104. As with loading, the unloading can be performed on any desired shelf 104 without a predetermined order (e.g., it is not required to unload the top shelf, then the next highest shelf, etc.). Instead, any shelf can be unloaded without regard to the status of any other shelf. For instance, in one scenario all of the shelves are loaded and combination electronic assembly 214(3) on shelf 104(3) is scheduled to be unloaded and serviced or replaced. To unload, the carrier 116 can be positioned relative to shelf 104(3) until unloaded pin 228 is aligned with hole 308(3). This will position the carrier 116 slightly below shelf 104(3). In this case, ‘slightly’ means that the carrier 116 is below shelf 104(3) and does not contact shelf 104(3), combination electronic assembly 214(3), or combination electronic assembly 214(2), on the underlying shelf 104(2) during horizontal displacement. Once the carrier 116 is fully displaced under shelf 104(3), unloaded pin 228 can be removed from hole 308(3), the moveable element 222 can be raised vertically until loaded pin 226 is aligned with hole 306(3). This process will raise the carrier 116 until it supports the combination electronic assembly 214(3) and lifts the combination electronic assembly 214(3) off of the shelf 104(3). The carrier 116 and the combination electronic assembly 214(3) can then be withdrawn from the multi-shelf chassis 102.

As mentioned above, the extent of the horizontal displacement can be determined by the stops 208 (FIG. 2E). Once the stops engage, loaded pin 226 can be withdrawn, the vertical positioning mechanism 118 can be lowered slightly, and unloaded pin 228 can be engaged into hole 308(3). This slight lowering will position the combination electronic assembly 214 on the shelf 104(3) (e.g., the combination electronic assembly 214 is now supported by the shelf rather than the carrier). Various actions can be taken to keep the electronic assembly from moving on the shelf. These aspects are discussed below relative to FIGS. 5A-5F. Once the electronic assembly is positioned on the shelf, the carrier 116, which is now positioned slightly under the shelf can now be withdrawn horizontally out of the multi-shelf chassis 102.

Some implementations can employ carrier guide blocks 310. The carrier guide blocks can operate relative to the carrier 116 to maintain the carrier 116 parallel to the shelf 104 during the installation process. The carrier guide blocks 310 can be made out of low friction material such as Ultra High Molecular Weight (UHMW) or Delrin to provide smooth surfaces for engagement with the carrier.

FIGS. 4A-4C show example rate limiters 402 that can be employed relative to the vertical positioning mechanism 118 of the loader tool 114. The rate limiters 402 can control the rate of vertical movement of the moveable element 222 relative to the fixed element to reduce/avoid damage to the loader tool 114 and/or the electronic assembly 106 positioned on the loader tool 114. In FIG. 4A, the rate limiter 402 is represented schematically as a pair of opposing constant force springs 404 (e.g., upper and lower constant force springs) that extend between the moveable element 222 and the fixed element 220.

In FIG. 4B, the rate limiter 402 is represented schematically as a pair of opposing dampening cylinders 406 (e.g., upper and lower dampening cylinders) extending between the moveable element 222 relative to the fixed element 220.

In FIG. 4C, the rate limiter 402 includes a serrated or sawtooth surface 408 on the fixed element 220 facing the moveable element 222. The sawtooth surface 408 include alternating teeth 410 and valleys 412. A spring plunger 414 is biased into the valleys 412 between the teeth 410. For each tooth 410 to pass the plunger 414, the tooth pushes the plunger 414 away from the fixed element 220 and then the plunger 414 is biased into the next valley 412. This process slows relative movement between the fixed element 220 and the moveable element 222.

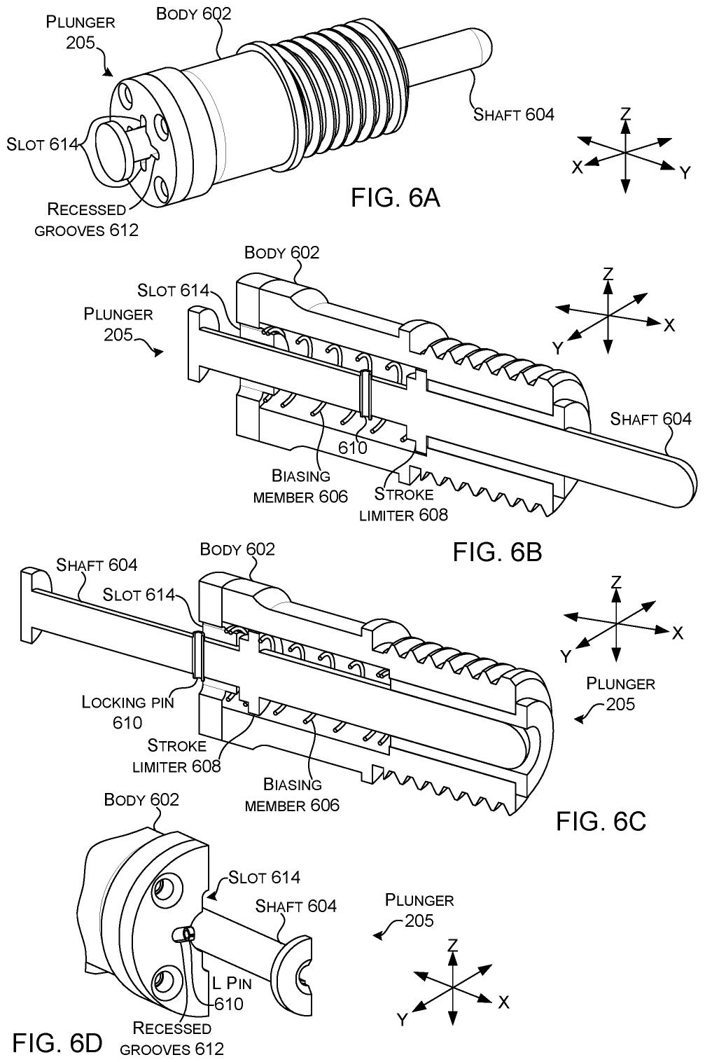

FIGS. 5A-5F collectively show details of example anti-deflection mechanism 202 and the pair of opposing plungers 205. FIG. 5A shows the anti-deflection mechanism 202 in isolation. FIG. 5B shows a carrier 116 loaded with electronic assembly 106 positioned relative to shelf 104(6). Note that the carrier 116 and the receiver 122 are occluding shelf 104(6), but the other shelves are readily visible. FIG. 5B also shows the pair of plungers 205(6) deployed under carrier 116. The remaining plungers 205(1)-205(5) remain undeployed. Details of the plungers 205 are described below relative to FIGS. 6A-6D.

FIG. 5B also shows that in this implementation, the wedge lock sliding panel 230 defines slots 502 and the anti-deflection mechanism 202 defines pins 504. The slots 502 are oriented horizontally and define a range of horizontal displacement of the wedge lock sliding panels 230. This aspect is described in more detail below relative to FIGS. 5C-5E.

FIGS. 5C-5E show a sequence relating to electronic assembly deployment. FIG. 5C shows an enlarged view of a portion of the view shown in FIG. 5B. Note that plunger 205(6) is deployed and is supporting the carrier 116. The supported carrier is holding the electronic assembly 106 above the shelf 104(6). As described above relative to FIGS. 3A-3F, at this point loaded pin 226 would be in hole 306(6) so that the carrier 116 positions the electronic assembly 106 slightly above the shelf 104(6). As illustrated in FIG. 5C at the distal end of the deployed shelf, plungers 205(6) contribute to the uniform height of the carrier 116 (e.g., reduce deflection of the distal end).

FIG. 5D shows a subsequent point in the electronic assembly installation. At this point, the plungers 205(6) have been withdrawn (e.g., are no longer supporting the carrier 116). Also, referring again to FIGS. 3A-3F, at this point, loaded pin 226 would be withdrawn from hole 306(6), the vertical positioning mechanism 118 would be lowered slightly, and the unloaded pin 228 would be inserted into hole 308(6). Removing the plungers 205 and lowering the vertical positioning mechanism 118 lowers the position of the carrier 116, such that as illustrated in FIG. 5D, the electronic assembly 106 is now supported by the shelf 104(6).

FIGS. 5E and 5F shows a subsequent point where the carrier 116 has been withdrawn (e.g., is not shown) and the electronic assembly 106 is positioned on the shelf 104(6). Further, the wedge lock sliding panel 230 has been moved inwardly to restrict movement of the electronic assembly 106. This is evidenced by comparing FIG. 5D wherein the pins 504 are at the inward end of the slots 502 (e.g., right side in FIG. 5D) to FIG. 5E where the pins are at the outward end of the slots 502 (e.g., left side in the FIG. 5E). As can be seen in FIG. 5F, in this case the electronic assembly 106 includes the two blade computers 216, and the wedge lock sliding panels 230 can define and control the locations of the blade computers on the shelf 104(6). The wedge lock sliding panels 230 can hold the blade computers 216 while the wedge lock adjusters (219, FIG. 2B) are employed to expand the wedge locks 218 to lock the blade computers 216 against opposing surfaces of multi-shelf chassis 102 (e.g., between a shelf and an opposing surface above the shelf). Once the wedge locks 218 are locked, the wedge lock sliding panels 230 can be returned to the position of FIG. 5D.

To summarize from one perspective, the anti-deflection mechanism 202 can include a series of plungers 205 (e.g., one per shelf per side) and low friction wedge lock sliding panels 230. The carrier 116 can have a relatively small cross-sectional profile. As such, the carrier tends to deflect whether loaded or unloaded (e.g., with or without an electronic assembly 106 on it). Therefore, the anti-deflection mechanism 202 can be utilized to reduce/prevent the carrier 116 from deflecting. The anti-deflection mechanism 202 can be inserted through the multi-shelf chassis 102 relative to an individual shelf before horizontally inserting the loaded carrier 116. By activating the spring plungers 205 for the individual shelf that is being loaded, the anti-deflection mechanism 202 can keep the carrier straight and/or reduce misalignment between the carrier and the multi-shelf chassis. After the loaded carrier is inserted, since there may not be rigid connection between the two blade computers, both blade computers 216 have a tendency of being pushed toward each other when torquing the wedge lock sliding panels 230 on the blade computers. Therefore, four wedge lock sliding panels 230 can be utilized as a “stop” to prevent the blade computers 216 from sliding inside the multi-shelf chassis until the wedge locks 218 are engaged.

FIGS. 6A-6D collectively show details of example plunger 205. In this case, the plunger 205 can include a body 602, a shaft 604, a biasing member 606, and/or a stroke limiter 608. The body 602 can be secured to a larger assembly, such as the anti-deflection mechanism 202. In the illustrated example, the body 602 is threaded and can be received in corresponding threads formed in the anti-deflection mechanism 202 relative to an individual shelf. The shaft 604 can travel within the body 602. In this case the biasing member 606, such as a spring, can bias the shaft to either a fully deployed position (e.g., FIG. 6B) or a undeployed position (e.g., FIG. 6C). The stroke limiter 608 can work cooperatively with the body 602 to define a displacement of the shaft 604 from the undeployed to the deployed positions.

The plunger 205 can also employ a lock to maintain the shaft 604 in the undeployed position and/or the deployed position. In this case, the lock includes a locking pin 610 and recessed grooves 612. To lock the plunger 205 in the undeployed position, the shaft 604 can be turned until the locking pin 610 is aligned with the recessed grooves 612 in the body 602. The shaft 604 can be deployed very slightly to capture the locking pin 610 in the recessed grooves 612. The plunger 205 can be unlocked for deployment by pulling the shaft 604 back slightly and turning the shaft so the locking pin 610 is not aligned with the recessed grooves 612 and is instead aligned with slots 614, which allow the pin 610 to pass through the body 602. Stated another way, the recessed grooves 612 are only formed part way through the body 602 (e.g., controlled depth blind vias). The slots 614 are formed through the entire body 602 (e.g., through vias). Thus, positioning the locking pin 610 in the recessed grooves 612 traps the locking pin 610 and prevents further deployment of the shaft 604 as shown in FIG. 6D. Positioning the locking pin 610 in the slots 614 allows the locking pin 610 (and hence the shaft 604) to travel forward toward the deployed configuration of FIGS. 6A and 6B.

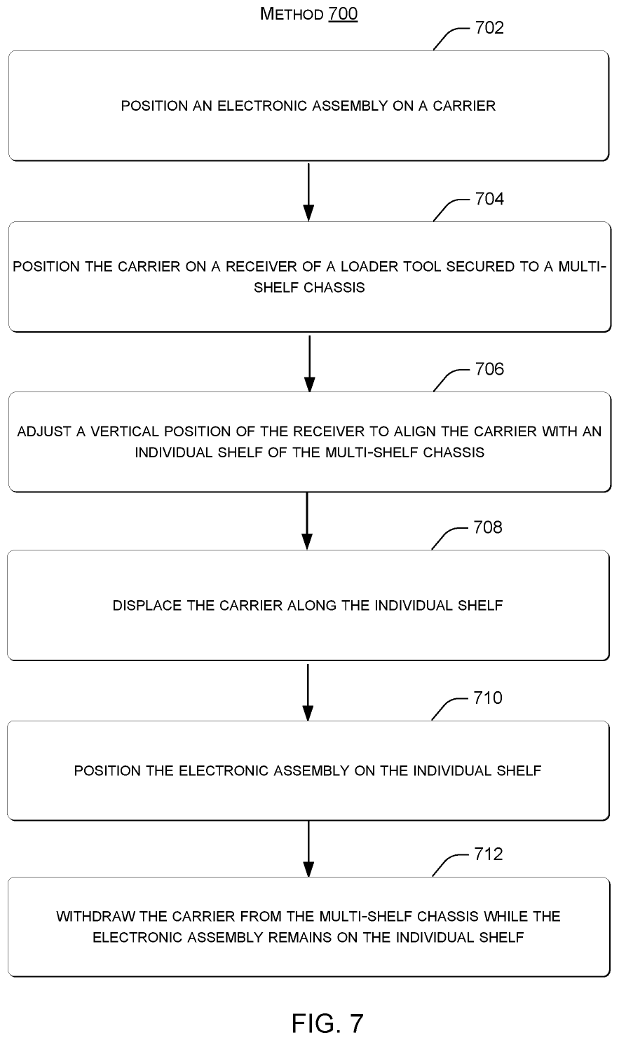

FIG. 7 shows an example flowchart of a multi-shelf chassis loading technique or method 700.

At 702 the method can position an electronic assembly on a carrier. In some cases, the positioning can entail positioning multiple physically discrete electronic assemblies on the carrier. For instance, two separate communicatively coupled blade computers could be positioned on the carrier. In some implementations, the positioning can entail locking the multiple physically discrete electronic assemblies to the carrier so that they don't move relative to each other and/or the carrier during the installation.

At 704 the method can position the carrier on a receiver of a loader tool secured to a multi-shelf chassis. For instance, the positioning can entail associating intermeshing elements of the carrier and the loader tool. The intermeshing elements can allow smooth low-friction horizontal movement of the carrier relative to the receiver.

At 706 the method can adjust a vertical position of the receiver to align the carrier with an individual shelf of the multi-shelf chassis. The adjusting can include multiple levels of granularity. For instance, the adjusting can entail aligning the loaded carrier relative to the individual shelf and then adjusting the carrier relative to that individual shelf depending upon whether the carrier is loaded or unloaded.

At 708 the method can displace the carrier along the individual shelf. In some cases, an interaction of the carrier and the loader tool, such as the receiver can define an extent of the horizontal displacement. In some configurations, the horizontal displacement of the carrier occurs while the carrier holds the electronic assembly above the individual shelf. In some configurations, actions can be taken to limit vertical deflection of the carrier during the displacement. For instance, anti-deflection solutions can be employed that maintain a planar and horizontal configuration of the carrier during the deployment.

At 710 the method can position the electronic assembly on the individual shelf. The positioning can entail lowering the carrier so that the electronic assembly is supported by the shelf and the carrier is below the shelf. In some cases, the electronic assembly can be locked on the shelf to prevent movement.

At 712 the method can withdraw the carrier from the multi-shelf chassis while the electronic assembly remains on the individual shelf. The anti-deflection techniques can be ceased. The carrier can now be loaded with another electronic assembly for positioning on another individual shelf. The method can be repeated for as many shelves of the multi-shelf chassis as desired. Further, the method can be reversed to remove electronic assemblies for service and/or replacement.

The method allows a high density of electronic assemblies to be positioned on an individual shelf and for a high density of electronic assemblies to be achieved in the volume of the multi-shelf chassis because the loader tool can accommodate small shelf-to-shelf distances. Further, because discrete electronic assemblies can be positioned on an individual shelf, the multi-shelf chassis can manage operating conditions for the individual electronic assemblies differently. For instance, the operating temperature for electronic assemblies positioned at the loading end of the multi-shelf chassis can be managed at a first temperature, while the operating temperature for electronic assemblies positioned at the opposite end can be managed at a second different temperature.

The described methods can be performed by the systems and/or elements described above and/or below, and/or by other devices and/or systems.

The order in which the methods are described is not intended to be construed as a limitation, and any number of the described acts can be combined in any order to implement the method, or an alternate method. Furthermore, the method can be implemented in any suitable hardware, software, firmware, or combination thereof, such that a device can implement the method. In one case, the method is stored on one or more computer-readable storage medium/media as a set of instructions (e.g., computer-readable instructions or computer-executable instructions) such that execution by a processor causes the processor to perform the method.

Multiple implementations are described above. Additional implementations are described below. One such implementation is a system. The system can include a multi-shelf chassis comprising multiple stacked shelves configured to receive electronic assemblies and an electronic assembly loader tool comprising a carrier that supports an individual electronic assembly during installation and removal from the multi-shelf chassis. The electronic assembly loader tool further comprising a vertical positioning mechanism configured to align the carrier with an individual shelf during installation and removal of the individual electronic assembly and a horizontal positioning mechanism configured to extend the carrier into the multi-shelf chassis to position the individual electronic assembly on the individual shelf and withdraw the carrier from the multi-shelf chassis.

Another implementation can include any of the above and/or below implementations where the electronic assemblies comprise blade computers.

Another implementation can include any of the above and/or below implementations where each blade computer comprises two or more physically distinct communicably coupled blades.

Another implementation can include any of the above and/or below implementations where the physically distinct blades are communicably coupled by conductive tapes.

Another implementation can include any of the above and/or below implementations where the carrier physically supports the conductive tapes.

Another implementation can include any of the above and/or below implementations where the carrier comprises locators for positively positioning the distinct blades.

Another implementation can include any of the above and/or below implementations where the carrier comprises stops that define an extent of horizontal movement of the carrier into the multi-shelf chassis.

Another implementation includes an electronic assembly loader tool comprising a vertical positioning mechanism configured to be secured to a multi-shelf chassis and to align a carrier supporting multiple electronic assemblies with an individual shelf of the multi-shelf chassis, the vertical positioning mechanism defining a loaded height that is above the individual shelf and an unloaded height that is below the individual shelf and a horizontal positioning mechanism configured to extend the carrier into the multi-shelf chassis at the loaded height to a horizontal extent defined by the carrier and to be lowered to the unloaded height to position the multiple electronic assemblies on the individual shelf and withdraw the carrier from the multi-shelf chassis at the unloaded height.

Another implementation can include any of the above and/or below implementations where the vertical positioning mechanism comprises a fixed element and a moveable element, wherein the fixed element is secured to the multi-shelf chassis and the moveable element moves vertically relative to the fixed element.

Another implementation can include any of the above and/or below implementations where the fixed element defines rails and the moveable element defines channels that receive the rails to allow the moveable element to be moved from the individual shelf to another individual shelf.

Another implementation can include any of the above and/or below implementations where relative to the individual shelf the fixed element defines a loaded hole that is higher than an unloaded hole.

Another implementation can include any of the above and/or below implementations where the moveable element defines a loaded pin and an unloaded pin and wherein the loaded height is defined by the loaded pin in the loaded hole.

Another implementation can include any of the above and/or below implementations where the carrier is lowered to the unloaded height by removing the loaded pin from the loaded hole and inserting the unloaded pin into the unloaded hole.

Another implementation can include any of the above and/or below implementations where the electronic assembly loader tool further comprises an anti-deflection mechanism that is configured to support a distal end of the carrier when the carrier is extended into the multi-shelf chassis along the individual shelf by the horizontal positioning mechanism.

Another implementation can include any of the above and/or below implementations where the anti-deflection mechanism comprises a pair of opposing deployable plungers that when deployed support the distal end above the shelf.

Another implementation includes an electronic assembly loader tool comprising a vertical positioning mechanism configured to be secured to a multi-shelf chassis and to align a carrier supporting an electronic assembly with an individual shelf of the multi-shelf chassis, a horizontal positioning mechanism configured to extend the carrier along the individual shelf, and an anti-deflection mechanism configured to reduce downward deflection of the carrier when the carrier is extended into the multi-shelf chassis along the individual shelf.

Another implementation can include any of the above and/or below implementations where relative to the individual shelf, the vertical positioning mechanism positions the carrier supporting the electronic assembly above the individual shelf.

Another implementation can include any of the above and/or below implementations where the horizontal positioning mechanism is configured to extend the carrier supporting the electronic assembly into the multi-shelf chassis above the individual shelf to a defined extent.

Another implementation can include any of the above and/or below implementations where at the defined extent the vertical positioning mechanism is configured to lower the carrier so that the electronic assembly is positioned on the individual shelf and is no longer supported by the carrier.

Another implementation can include any of the above and/or below implementations where at the defined extent the horizontal positioning mechanism is configured to withdraw the carrier below the individual shelf so that the electronic assembly remains on the individual shelf.

Another implementation can include any of the above and/or below implementations where at the defined extent the vertical positioning mechanism further comprises a rate limiter that controls a rate that the carrier is lowered.

Another implementation can include any of the above and/or below implementations where the rate limiter comprises opposing upper and lower constant force springs secured between a moveable element of the vertical positioning mechanism and a fixed element of the vertical positioning mechanism.

Another implementation can include any of the above and/or below implementations where the rate limiter comprises opposing upper and lower dampening cylinders secured between a moveable element of the vertical positioning mechanism and a fixed element of the vertical positioning mechanism.

Another implementation can include any of the above and/or below implementations where the anti-deflection mechanism comprises multiple deployable plungers oriented along the multi-shelf chassis with individual deployable plungers aligned relative to individual shelves so that an individual deployable plunger can be deployed to support the carrier as the carrier is extended into the multi-shelf chassis along the individual shelf.

Another implementation can include any of the above and/or below implementations where the vertical positioning mechanism is secured to a first end of the multi-shelf chassis and the horizontal positioning mechanism displaces the carrier and the electronic assembly from the first end into the multi-shelf chassis along the shelf toward an opposite end, and wherein the deployable plungers are positioned proximate to the opposite end.

Another implementation includes a method comprising positioning an electronic assembly on a carrier, positioning the carrier on a receiver of a loader tool secured to a multi-shelf chassis, adjusting a vertical position of the receiver to align the carrier with an individual shelf of the multi-shelf chassis, displacing the carrier along the individual shelf, positioning the electronic assembly on the individual shelf, and withdrawing the carrier from the multi-shelf chassis while the electronic assembly remains on the individual shelf.

Another implementation can include any of the above and/or below implementations where the positioning the electronic assembly on the carrier comprises positioning multiple physically discrete electronic assemblies on the carrier.

Another implementation can include any of the above and/or below implementations where the adjusting comprises adjusting the receiver to align with the individual shelf without first having to load or unload any other shelves of the multi-shelf chassis.

Another implementation can include any of the above and/or below implementations where the positioning the electronic assembly on the individual shelf comprises positioning an entirety of the electronic assembly on the individual shelf simultaneously rather than sequentially.

Another implementation can secure a loader tool to a multi-shelf chassis that includes at least one shelf supporting an electronic assembly, the loader tool comprising a carrier. The implementation can vertically align the loader tool so the carrier is positioned below the at least one shelf of the multi-shelf chassis and above an adjacent underlying shelf. The implementation can horizontally displace the carrier along the at least one shelf, vertically raise the carrier so that the electronic assembly is supported by the carrier and not the at least one shelf, and horizontally withdraw the carrier and the electronic assembly from the multi-shelf chassis.

### CONCLUSION

Although the subject matter relating to a multi-shelf loading has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. An electronic assembly loader tool, comprising:
a vertical positioning mechanism configured to be secured to a multi-shelf chassis and to align a carrier supporting multiple electronic assemblies with an individual shelf of the multi-shelf chassis, the vertical positioning mechanism defining a loaded height that is above the individual shelf and an unloaded height that is below the individual shelf, and,
a horizontal positioning mechanism configured to extend the carrier into the multi-shelf chassis at the loaded height to a horizontal extent defined by the carrier and to be lowered to the unloaded height to position the multiple electronic assemblies on the individual shelf and withdraw the carrier from the multi-shelf chassis at the unloaded height.

2. The electronic assembly loader tool of claim 1, wherein the vertical positioning mechanism comprises a fixed element and a moveable element, wherein the fixed element is secured to the multi-shelf chassis and the moveable element moves vertically relative to the fixed element.

3. The electronic assembly loader tool of claim 2, wherein the fixed element defines rails and the moveable element defines channels that receive the rails to allow the moveable element to be moved from the individual shelf to another individual shelf.

4. The electronic assembly loader tool of claim 3, wherein relative to the individual shelf the fixed element defines a loaded hole that is higher than an unloaded hole.

5. The electronic assembly loader tool of claim 4, wherein the moveable element defines a loaded pin and an unloaded pin and wherein the loaded height is defined by the loaded pin in the loaded hole.

6. The electronic assembly loader tool of claim 5, wherein the carrier is lowered to the unloaded height by removing the loaded pin from the loaded hole and inserting the unloaded pin into the unloaded hole.

7. The electronic assembly loader tool of claim 1, further comprising an anti-deflection mechanism that is configured to support a distal end of the carrier when the carrier is extended into the multi-shelf chassis along the individual shelf by the horizontal positioning mechanism.

8. The electronic assembly loader tool of claim 7, wherein the anti-deflection mechanism comprises a pair of opposing deployable plungers that when deployed support the distal end above the shelf.

9. An electronic assembly loader tool, comprising:
a vertical positioning mechanism configured to be secured to a multi-shelf chassis and to align a carrier supporting an electronic assembly with an individual shelf of the multi-shelf chassis;
a horizontal positioning mechanism configured to extend the carrier along the individual shelf; and,
an anti-deflection mechanism configured to reduce downward deflection of the carrier when the carrier is extended into the multi-shelf chassis along the individual shelf.

10. The electronic assembly loader tool of claim 9, wherein relative to the individual shelf, the vertical positioning mechanism positions the carrier supporting the electronic assembly above the individual shelf.

11. The electronic assembly loader tool of claim 10, wherein the horizontal positioning mechanism is configured to extend the carrier supporting the electronic assembly into the multi-shelf chassis above the individual shelf to a defined extent.

12. The electronic assembly loader tool of claim 11, at the defined extent the vertical positioning mechanism is configured to lower the carrier so that the electronic assembly is positioned on the individual shelf and is no longer supported by the carrier.

13. The electronic assembly loader tool of claim 12, at the defined extent the horizontal positioning mechanism is configured to withdraw the carrier below the individual shelf so that the electronic assembly remains on the individual shelf.

14. The electronic assembly loader tool of claim 12, at the defined extent the vertical positioning mechanism further comprises a rate limiter that controls a rate that the carrier is lowered.

15. The electronic assembly loader tool of claim 14, wherein the rate limiter comprises opposing upper and lower constant force springs secured between a moveable element of the vertical positioning mechanism and a fixed element of the vertical positioning mechanism.

16. The electronic assembly loader tool of claim 14, wherein the rate limiter comprises opposing upper and lower dampening cylinders secured between a moveable element of the vertical positioning mechanism and a fixed element of the vertical positioning mechanism.

17. The electronic assembly loader tool of claim 10, wherein the anti-deflection mechanism comprises multiple deployable plungers oriented along the multi-shelf chassis with individual deployable plungers aligned relative to individual shelves so that an individual deployable plunger can be deployed to support the carrier as the carrier is extended into the multi-shelf chassis along the individual shelf.

18. The electronic assembly loader tool of claim 17, wherein the vertical positioning mechanism is secured to a first end of the multi-shelf chassis and the horizontal positioning mechanism displaces the carrier and the electronic assembly from the first end into the multi-shelf chassis along the shelf toward an opposite end, and wherein the deployable plungers are positioned proximate to the opposite end.

19. A method, comprising:
positioning an electronic assembly on a carrier;
positioning the carrier on a receiver of a loader tool secured to a multi-shelf chassis;
adjusting a vertical position of the receiver to align the carrier with an individual shelf of the multi-shelf chassis;
displacing the carrier along the individual shelf;
positioning the electronic assembly on the individual shelf; and,
withdrawing the carrier from the multi-shelf chassis while the electronic assembly remains on the individual shelf.

20. The method of claim 19, wherein the positioning the electronic assembly on the carrier comprises positioning multiple physically discrete electronic assemblies on the carrier.
